(19) United States
(12) Patent Application Publication
(10) Pub. No.: US 2024/0273259 A1
(43) Pub. Date: Aug. 15, 2024

(54) STANDARDIZED RELATIVE PERMEABILITY CURVES FOR GREEN FIELDS

(71) Applicant: Saudi Arabian Oil Company, Dhahran (SA)

(72) Inventors: Adly Khalil Muslumani, Dhahran (SA); Ghazi Kraishan, Dhahran (SA); Ahmed Muthana, Dhahran (SA); Nabil Bulushi, Dhahran (SA); Rayan Adil Ghanim, Dhahran (SA); Tareq M. Zahrani, Dhahran (SA); Abdullah A. Hamidi, Dhahran (SA)

(21) Appl. No.: 18/107,587

(22) Filed: Feb. 9, 2023

(51) Int. Cl. G06F 30/27; E21B 49/00; G01V 11/00

(52) U.S. Cl. CPC G06F 30/27; E21B 49/00; G01V 11/00; E21B 2200/20

(57) ABSTRACT

Systems and methods include a computer-implemented method for generating permeability curves. Petrophysical rock type (PRT) is determined for a well as a function of porosity (Φ) and permeability (K). Special core analysis (SCAL) data is classified based on PRT porosity and permeability distribution on a SCAL group. A representative relative permeability curve is generated from each SCAL group.

### TECHNICAL FIELD

The present disclosure applies to determining permeability in rock formations.

### BACKGROUND

Obtaining a relative permeability profile with its endpoints is a key process in dynamic modeling and has a significant impact on the history matching process. Relative permeability (Kr) measurements are typically acquired mainly by special core analysis (SCAL) which is a time-consuming and expensive process. Despite their importance, in many cases, these measurements are either not available or limited to certain reservoir facies.

### SUMMARY

The present disclosure describes techniques that can be used for identifying petrophysical rock types for a new well, based on historical measurements and using the simulation model and relative permeability and porosity functions. In some implementations, a computer-implemented method includes the following. Petrophysical rock type (PRT) is determined for a well as a function of porosity (Φ) and permeability (K). Special core analysis (SCAL) data is classified based on PRT porosity and permeability distribution on a SCAL group. A representative relative permeability curve is generated from each SCAL group.

The previously described implementation is implementable using a computer-implemented method; a non-transitory, computer-readable medium storing computer-readable instructions to perform the computer-implemented method; and a computer-implemented system including a computer memory interoperably coupled with a hardware processor configured to perform the computer-implemented method, the instructions stored on the non-transitory, computer-readable medium.

The subject matter described in this specification can be implemented in particular implementations, so as to realize one or more of the following advantages. Technical problems are solved by using the techniques of the present disclosure, including: 1) problems associated with time-consuming special core analysis (SCAL) processes including laboratory experiment periods; 2) problems associated with having different engineers and experts performing different types of analyses, including maintaining old methods and analysis on SCAL data that are not fit for modern purposes; 3) problems associated with having a shortage (or lack of) data; 4) problems associated with the accessibility and availability of the data; and 5) problems associated with using analog. Technical solutions include the following. Techniques of the present disclosure make it possible to solve SCAL analysis problems facing engineers on new projects and new reservoirs, providing time-saving processes by reducing processing of SCAL data and analysis. SCAL analysis is standardized. Limited future data can be sufficient to find suitable and good-fitting data to use. There is no need to access multiple applications to obtain the data needed to perform a study. The use of analog data is avoided. The resource of relative permeability (Kr) curves development can be known and can be regenerated. This is helpful because, for many SCAL results determined long ago, the SCAL analysis that was performed to produce the Kr curves was not recorded.

The details of one or more implementations of the subject matter of this specification are set forth in the Detailed Description, the accompanying drawings, and the claims. Other features, aspects, and advantages of the subject matter will become apparent from the Detailed Description, the claims, and the accompanying drawings.

### DESCRIPTION OF DRAWINGS

FIG. 1 is a diagram showing an example of a workflow for determining a level of data filtration for identifying rock types, according to some implementations of the present disclosure.

FIG. 2 is a diagram showing an example of a workflow for determining standardized relative permeability curves for a green field, according to some implementations of the present disclosure.

FIG. 3 is a diagram showing an example of a flow corresponding to green fields data, according to some implementations of the present disclosure.

FIG. 4 is a diagram showing an example of a flow for a solution for green fields, according to some implementations of the present disclosure.

FIG. 5 is a diagram showing an example of a flow for a solution for green fields and legacy data, according to some implementations of the present disclosure.

FIG. 6 is a diagram showing examples of outputs from SCAL experiments, according to some implementations of the present disclosure.

FIG. 7 is a plot showing examples of petrophysical rock types that have been developed, according to some implementations of the present disclosure.

FIGS. 8A and 8B are graphs showing plots of well data for all experiments and after filtration, according to some implementations of the present disclosure.

FIG. 9 is a diagram showing an example of data flow including a normalization process and a de-normalization process, according to some implementations of the present disclosure.

FIG. 10A is a graph showing how an average oil relative permeability (Kro) curve fits within the range of the Kro data, according to some implementations of the present disclosure.

FIG. 10B is a graph showing how an average water relative permeability (Krw) curve fits within the range of the Krw data, according to some implementations of the present disclosure.

FIG. 11 is a plot showing an example of curve matching, according to some implementations of the present disclosure.

FIG. 12A is a flow chart of an example of a method for generating representative relative permeability curves, according to some implementations of the present disclosure.

FIG. 12B is a flow chart of an example of a method for identifying petrophysical rock types for a new well, according to some implementations of the present disclosure.

FIG. 13 is a block diagram illustrating an example computer system used to provide computational functionalities associated with described algorithms, methods, functions, processes, flows, and procedures as described in the present disclosure, according to some implementations of the present disclosure.

Like reference numbers and designations in the various drawings indicate like elements.

### DETAILED DESCRIPTION

The following detailed description describes techniques for identifying petrophysical rock types for a new well, based on historical measurements and using the simulation model and relative permeability and porosity functions. Various modifications, alterations, and permutations of the disclosed implementations can be made and will be readily apparent to those of ordinary skill in the art, and the general principles defined may be applied to other implementations and applications, without departing from the scope of the disclosure. In some instances, details unnecessary to obtain an understanding of the described subject matter may be omitted so as to not obscure one or more described implementations with unnecessary detail and inasmuch as such details are within the skill of one of ordinary skill in the art. The present disclosure is not intended to be limited to the described or illustrated implementations, but to be accorded the widest scope consistent with the described principles and features.

In some implementations, to facilitate relative permeability estimation, a large dataset can be created using validated measurements from various techniques of capillary pressure for both drainage and imbibition. From this set of data, petrophysical rock types can be identified based on Winland and Lucia techniques, e.g., as a function of porosity and permeability. A corresponding workflow can start by identifying rock types using porosity and permeability in new fields, with no or limited SCAL data, from which corresponding relative permeability functions are assigned, as defined in the dataset.

The present disclosure presents a case study in which SCAL data are used in the analysis. Since green fields do not have historical performance, a workflow can be implemented on a simulation model that has a long-production history. The workflow can include the use of porosity and permeability values in the simulation model to define rock types in the same way they are defined in the dataset. Corresponding relative permeability functions can then be assigned per rock type from the dataset. Results that have been obtained in experimentation and analysis indicate a very good starting point for a history match as compared with previously-defined rock types and associated relative permeability curves. These results imply that in green fields, with neither historical performance nor SCAL measurements, more representative rock types and relative permeability functions can be expected.

The workflow can help engineers to produce high-quality, data-driven relative permeability functions from porosity and permeability values in fields that have limited or no SCAL measurements. As more SCAL measurements are obtained from the new fields and reservoirs, the workflow is updated and uses this new information to reproduce the relative permeability functions.

The benefits of this workflow include the following. A thorough quality controlled procedure for relative permeability measurements is provided. A unique relative permeability measurement can be determined for each designed rock type. The measurements can include centrifuge imbibition, water relative permeability—max (Krw_max), and residual oil saturation (Sor). Centrifuge imbibition of capillary pressure (Pc) and Kr can be corrected from surface to down-hole. An ability is provided for regenerating the relative permeability curves whenever new SCAL data are found. A significant reduction of time is realized in the SCAL processing timeframe, hence saving time for simulation modeling. Prediction capabilities are possible in fields with similar properties.

In some implementations, a process for determining standardized relative permeability curves for green fields of the present disclosure can include: 1) determining PRT; 2) classifying SCAL data based on PRT porosity and permeability distribution on a group; and 3) generating one representative relative permeability curve for each SCAL group. In some implementations, for green fields, (Φ, K) may already be known from routine core analysis but not enough SCAL data exists to generate representative relative permeability curves. In this case, (Φ, K) can be used in a standardized PRT distribution. In case in which little/few SCAL experiments have been performed on a green field, (Φ, K) can be included, and Sor or other parameters can be changed. If no SCAL data exists, then the Kr curve can be used right away. In some experiments on minerals or dolomite, SCAL data can also be included.

For each rock type/petrophysical rock type (PRT), a representative relative permeability curve belonging to PRT can be generated. Each PRT can be identified as a function of porosity (Φ) and permeability (K). The PRT can be developed from Mercury Injection Capillary Pressure (MICP) experiments. After MICP data is collected and developing the PRT has started, additional steps can be included for accurate PRT identification, such as using the percentage of minerals, dolomite, density of the components. For example, it was discovered that due using MICP data, there are five PRTs clearly identified. However, after check the minerals, it was discovered that the PRT's should be increased to seven instead of five due to the difference of the rock components.

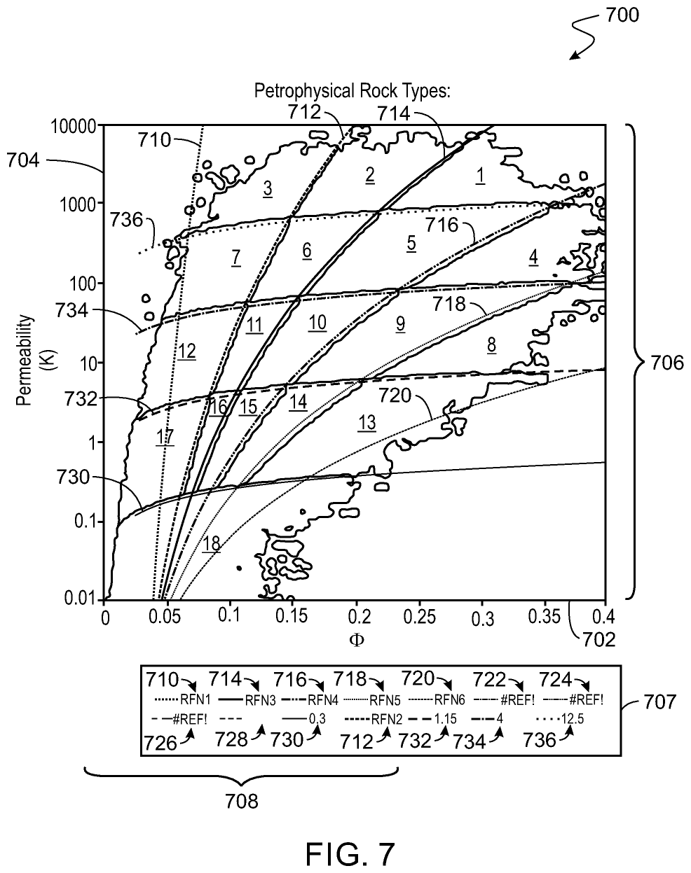

After it is determined that PRTs are developed and generated accurately, each PRT can be introduced as a function f(Φ, K). For example, for ten PRTs, the PRTs will have a range of (Φ, K), (Φ) on the x axis, and (K) on y-axis. Each PRT will have a limited area on the diagram of x-y axis, as shown in FIG. 7.

Analysis can also use SCAL experiments, SS, USS, and centrifuge (Pc, Kro). Each SCAL experiment has an associated (Φ, K). From the (Φ, K) for each SCAL experiments, it can be determined which experiment belongs to which PRT. The result is a list of SCAL experiments under each PRT.

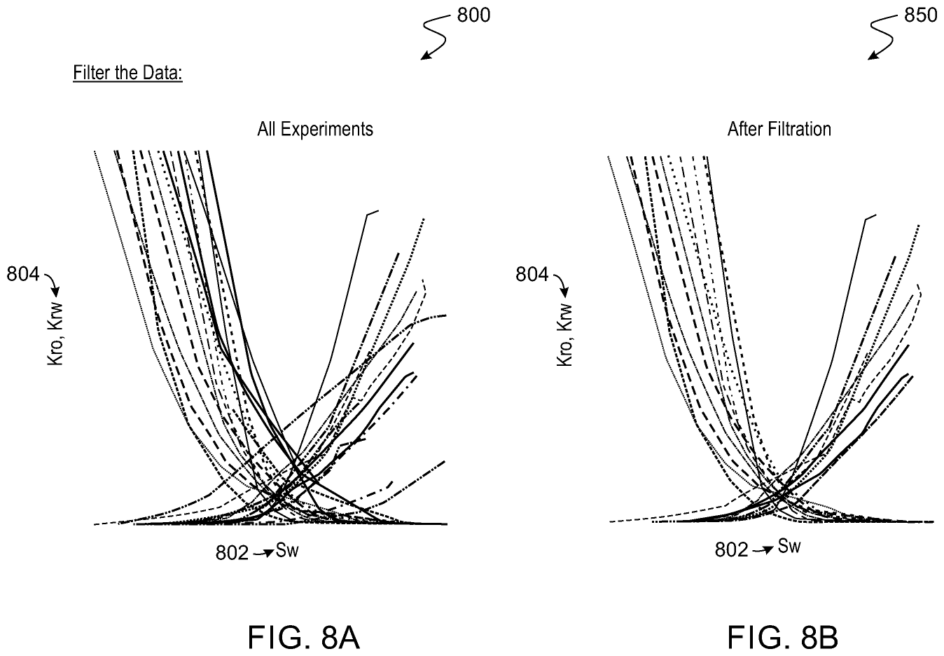

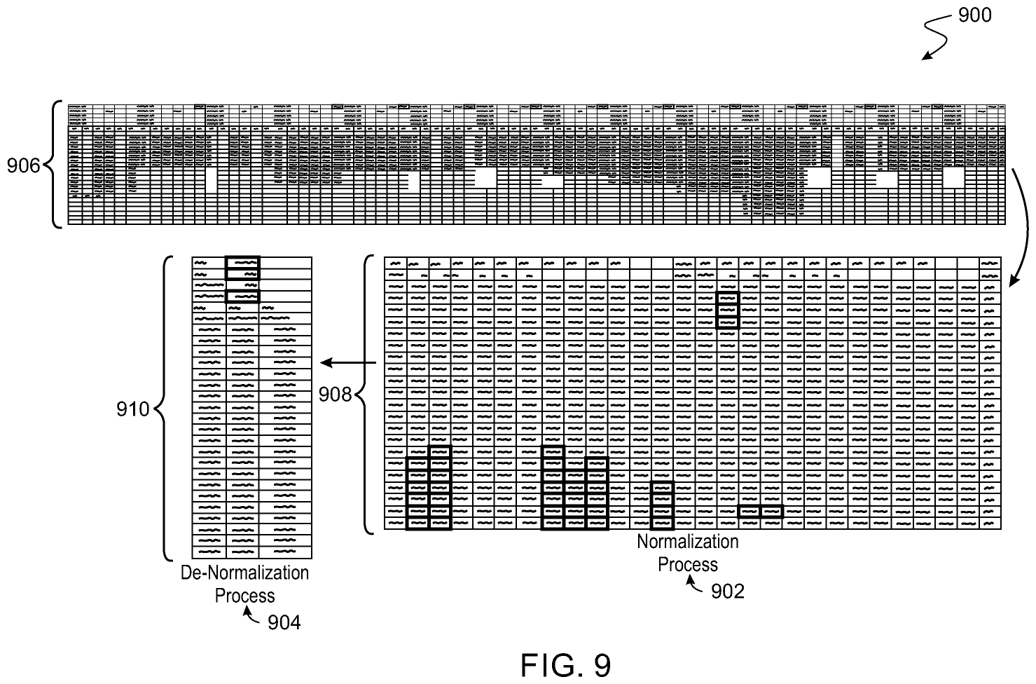

Analysis can work on each group of data separately (each PRT will have a group of SCAL experiments) as following. Kro/krw behavior can be visualized (See FIGS. 8A and 8B) For example, if ten curves exist, and one of the curves is shown to be different as compared to the other curves, then the curve can be removed. The average (residual oil saturation) Sor for each group can be measured, resulting in each PRT having one representative Sor. The average initial water saturation (Swi), Swir for each group can be measured, resulting in each PRT having one representative Swi/Swir. Normalization and De-Normalize processed can occur (See FIG. 9). Using this process, the Kro/Krw curves can be averaged in one curve.

Any green field can be used to implement the (Φ, K) values equation on PRT to know what PRTs a new field has. The Kr curve can be used, as can the SCAL data if the data exists.

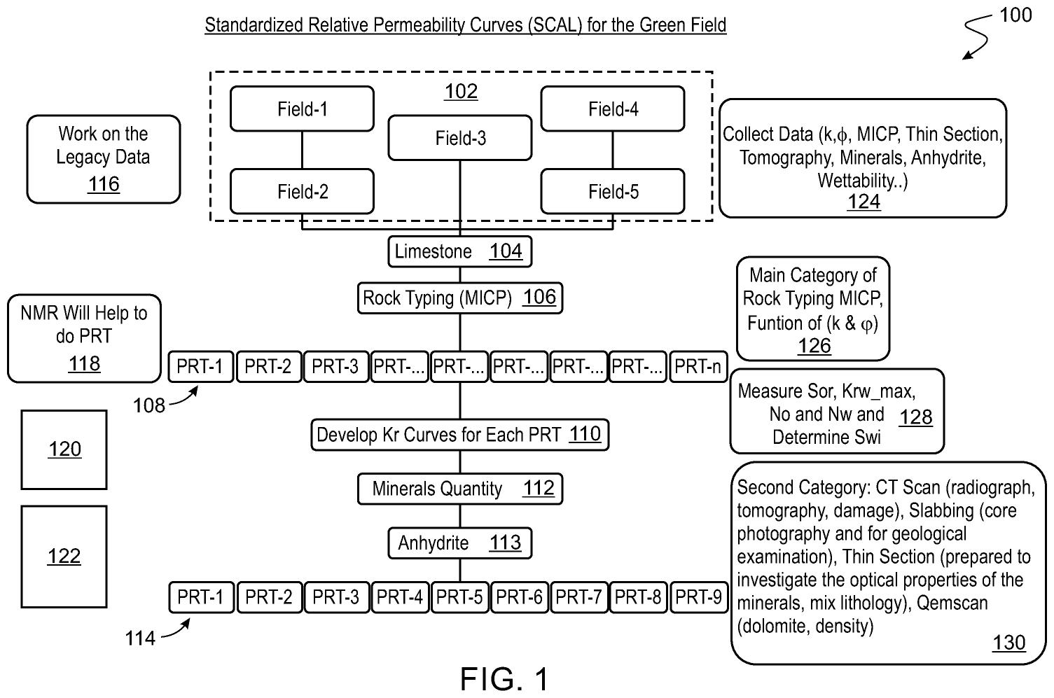

FIG. 1 is a diagram showing an example of a workflow 100 for determining a level of data filtration for identifying rock types, according to some implementations of the present disclosure. Limestone analysis 104 and rock typing 106 occur for fields 102, producing (118) PRTs 108. Kr curves are developed (110), from which minerals quantities (112) and anhydrite 113 are determined, resulting in determining PRTs 114. Legacy data 116 can be used for analyzing fields 102. Maps 120 and 122 are created. In order to improve PRT generation, petrophysics techniques and methodologies can include determining Anhydrite quantities and mineral percentages. For example, if PRT-1 includes a wide range of Anhydrite samples, then the petrophysics techniques can include dividing the PRT into two or three PRTs to make sure each PRT is reflecting the accurate reservoir behavior as shown in image 122. Also the petrophysics techniques can consider micro scale photographs and separate non-similar rock shapes as shown in image 120 Fields 102 are used to collect data 124, identify main categories of rock types 126, take measurements 128, and identify secondary categories of rock types 130.

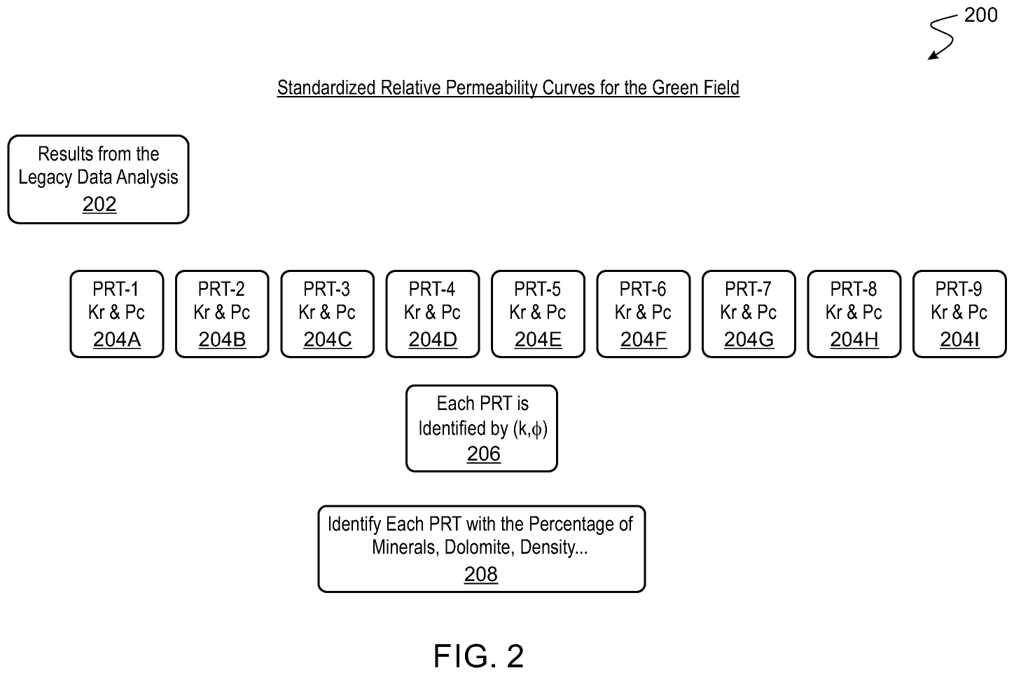

FIG. 2 is a diagram showing an example of a workflow 200 for determining standardized relative permeability curves for a green field, according to some implementations of the present disclosure. Results 202 from legacy data analysis 202 are used to identify PRTs 204A-204I. Each PRT is identified (206) by (Φ, K), and percentages of minerals, etc. 208.

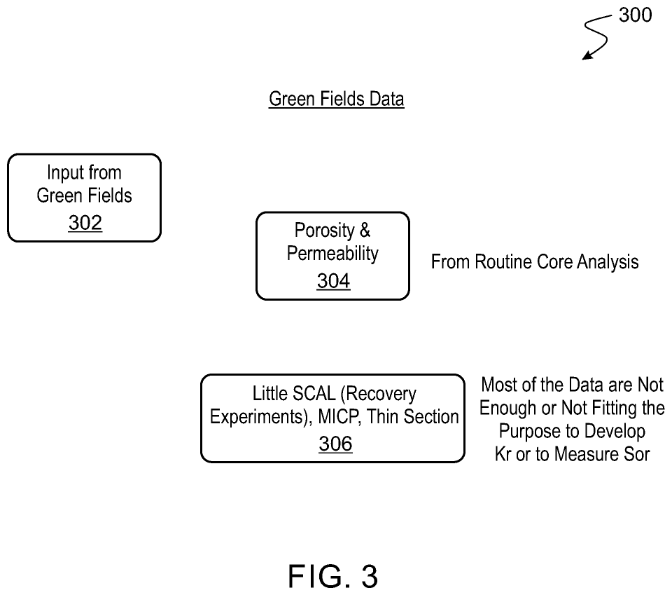

FIG. 3 is a diagram showing an example of a flow 300 corresponding to green fields data, according to some implementations of the present disclosure. Input 302 from green fields is used to determine (304) porosity and permeability. From that, additional information 306 is determined.

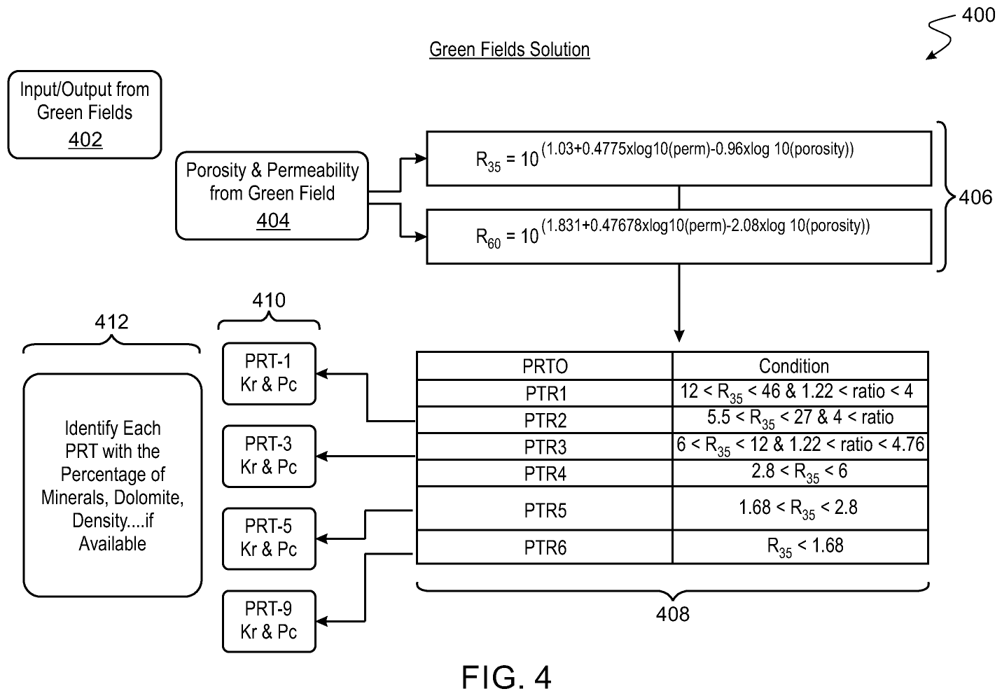

FIG. 4 is a diagram showing an example of a flow 400 for a solution for green fields, according to some implementations of the present disclosure. Input 402 from green fields is used to determine (404) porosity and permeability. Equations 406 can result from these steps. From that, PRTs 408 are determined. The right side of table 408 shows the petrophysical determined condition of each PRT. This includes the location of each PRT on a porosity/permeability chart. This provides an engineer with these conditions for use in simulations and/or SCAL analysis. The table 408 example uses six PRTs, using R35 in these six PRTs (others can use R60), where R35 is function of porosity and permeability. PRTs 410 and mineral percentages 412 are determined.

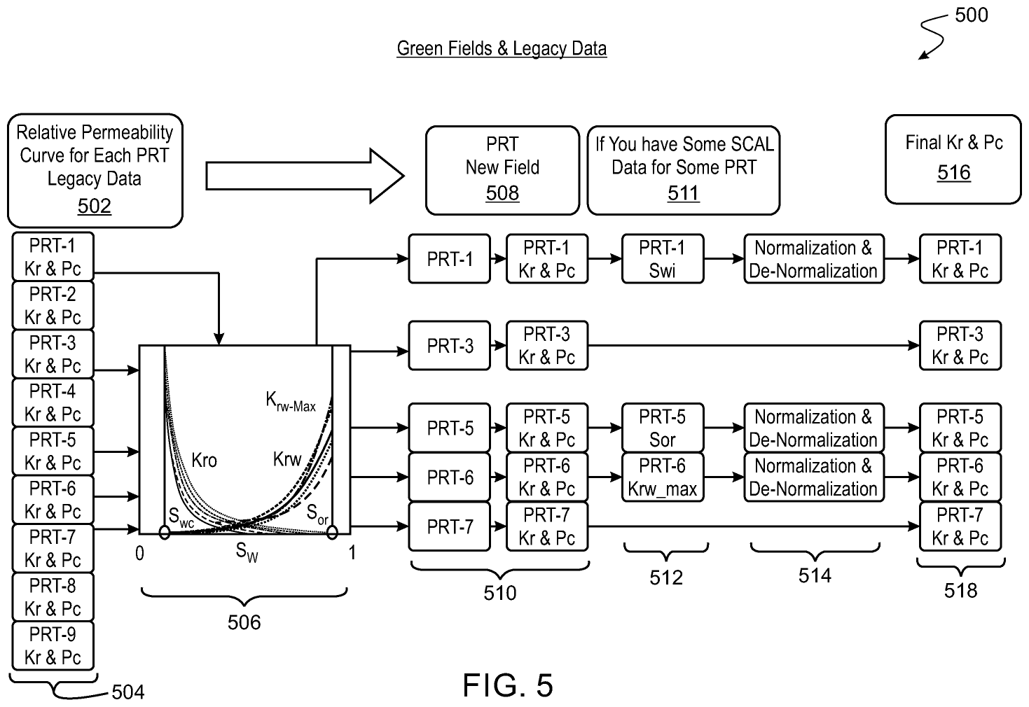

FIG. 5 is a diagram showing an example of a flow 500 for a solution for green fields and legacy data, according to some implementations of the present disclosure. At 502, relative permeability curves 506 for PRTs 504 are used to determine (508) PRT for a new field, e.g., based on PRTs 510. At 511, if SCAL data exists, PRTs 512 and used to in normalization/de-normalization 514 to produce (516) final PRTs 518.

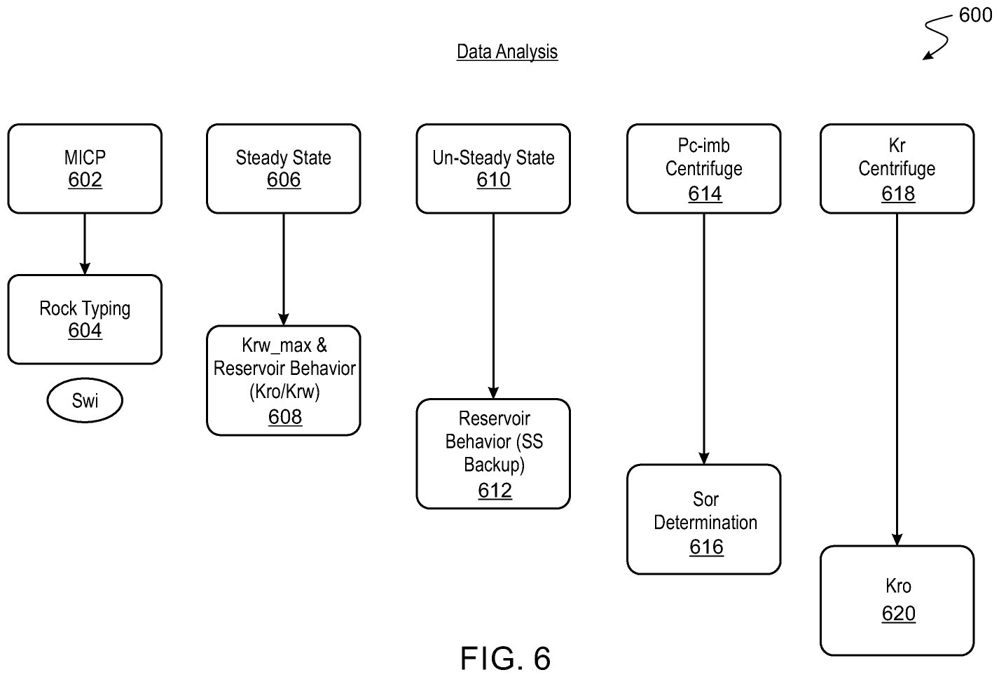

FIG. 6 is a diagram showing examples of outputs 600 from SCAL experiments, according to some implementations of the present disclosure. Names of the SCAL experiments are given in boxes 602, 606, 610, 614, and 618. The uses of the experiments are identified in boxes 604, 608, 612, 616, and 620, respectively. By using all Mercury Injection Capillary Pressure (MICP) data 602, 18 rock types have been developed through rock typing 604, resulting in 18 relative permeability curves. The rock typing can be applied to carbonate reservoir analysis using all SCAL data, including steady state (SS) 606, unsteady state (USS) 610, Pc_imb centrifuge 614, and Kr centrifuge 618. This information, including both oil relative permeability and capillary pressure and both drainage and imbibition, can be used to generate Krw_max and reservoir behavior (Kro/Krw) 608, reservoir behavior (SS backup) 612, Sor determination 616, and Kro 620. Using this approach, an engineer needs to provide porosity and permeability to be able to generate Kr curves for carbonate rocks, and the same can be implemented on the sandstone. Studies can be implemented separately on both limestone and sandstone. A general concept of the present disclosure is to develop relative permeability curves belonging to each PRT using all SCAL data for the carbonate reservoirs. A relative permeability (Kr) curve can be generated by analyzing data from SS, USS, and Kr centrifuge for oil information.

FIG. 7 is a plot 700 showing examples of petrophysical rock types that have been developed, according to some implementations of the present disclosure. For example, the petrophysical rock types can be the 18 rock types described with reference to FIG. 6. Rock types 706 of 18 types are plotted in the plot 700 relative to 702 and K 704. Key 707 identifies lines 710-736.

### Vision

A vision associated with the use of the techniques of the present disclosure includes the following. Relative permeability curves for green fields are standardized. This can provide an easy and quick way to generate Kr curves for new fields either with no data or with not enough data of SCAL. Kr and Pc curves for all limestone and sandstone reservoirs can be standardized. As a result, Kr curves for all fields can be assured to be under control of experts while implementing new methodologies of SCAL analysis. The number of petrophysical rock types (PRT's) can be maximized to provide improved accuracy and to cover all reservoir properties.

### Objectives

Objectives associated with the use of the techniques of the present disclosure include the following. SCAL analysis can be unified, specifically measurements of centrifuge imbibition (uses), including Krw_max and Sor as well as SS and USS (Conditioned). Centrifuge imbibition of Pc and Kr from surface to down-hole can be corrected. A quick method can be developed to generate Kr curves for any field. Shortages of data can be avoided. The use of analog data can be avoided. Rock typing implementation can be assured to be limited to using MICP and not Hydraulic Flow Unit (HFU). Rock typing can honor dynamic and static data. Rock typing can be implemented using geology, petrophysics, and engineering concepts.

### Legacy Data Analysis

Legacy data analysis can include the following. SCAL data and Routine Core Analysis (RCA) (porosity and permeability) data from all systems, file rooms, laboratories, and libraries can be collected. SCAL data, e.g., MICP, SS, USS, centrifuge, thin section, OEMscan, and X-ray, can be filtered. For example, non-homogenous Kr curve data on the same PRT group (Visualizing process) can be removed, or filtering can be based on the result of experiments, e.g., in the same group showing a variety of results for example high percentages of Anhydrite on certain experiments. All porosity, permeability, and MICP data can be sent to the Reservoir Description Division (RDD), instructing them to identify a maximum number of rock types using an MICP data set for a specific carbonate reservoir (e.g., based on R35 (e.g., Winland equation), Rock Fabric Number (RFN) (e.g., Lucia class), and PRT conditions.

Recovery experiments can be classified or customized for each PRT. Kr curves can be generated for each PRT. Other experiments (e.g., thin section, Qemscan, etc.) can be reviewed in case of rock type subdivision (e.g., needed in case of mixed limestone and dolomite intervals). In recovery experiments involving SS, USS, and centrifuge data, each experiment can be based on porosity and permeability, and each PRT has a range for both porosity and permeability. The porosity and permeability values can be used to identify a position in the PRT range. At the end, each recovery experiment can be classified as belonging to a particular PRT.

### Green Fields and Other Fields

All RCC data and available SCAL or any other experimental data can be collected. The (k, Φ) can be applied in the R₃₅ and conditions that are used in the legacy data. Each Kr and Pc can be assigned per PRT in the legacy data. Any other data can be gathered that can help to improve the final Kr curve classification, including petrography, X-ray diffraction, scanning electron microscopy (SEM), CT-Scan, core description, thin section, point count data, and diagenetics, and burial history of the reservoir.

FIGS. 8A and 8B are graphs 800 and 850 showing plots of well data for all experiments and after filtration, respectively, according to some implementations of the present disclosure. The plots are plotted relative to an Sw axis 802 and a Kro, Krw axis 804.

### Normalization and De-Normalization

FIG. 9 is a diagram showing an example of data flow 900 including a normalization process 902 and a de-normalization process 904, according to some implementations of the present disclosure. Data from SS experiments can be listed in spreadsheets 906, e.g., to ensure the Kr curves belong to the same PRT, with the number of spreadsheets depending on the number of rock types (e.g., one spreadsheet per PRT). The data can be normalized to a range from zero and one, e.g., to remove initial and endpoint effects. For example, the normalization process 902 can produce table 908 by normalizing the data in table 906. The average Krw_max, irreducible water saturation (Swi), and Sor for any particular PRT can be determined. De-normalization can be performed on certain points. For example, the de-normalization process 904 can produce table 910 by de-normalizing the data in table 908. Corey equations can be used to match the water relative permeability (Krw) and oil relative permeability (Kro) curves. Input parameters (e.g., No and Nw) can be derived to match the curves to enhance the final products.

### Final Results

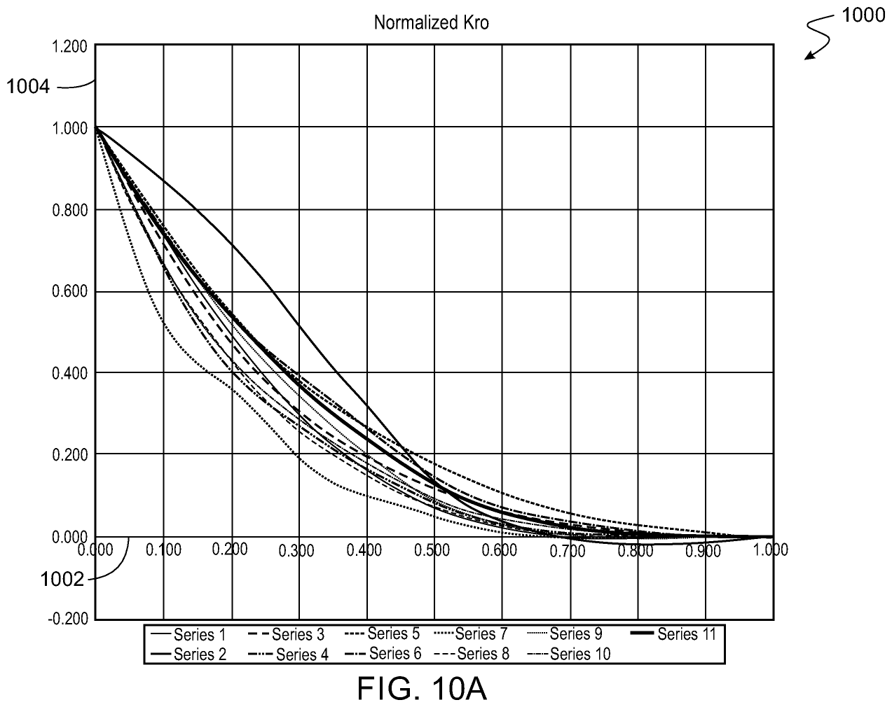

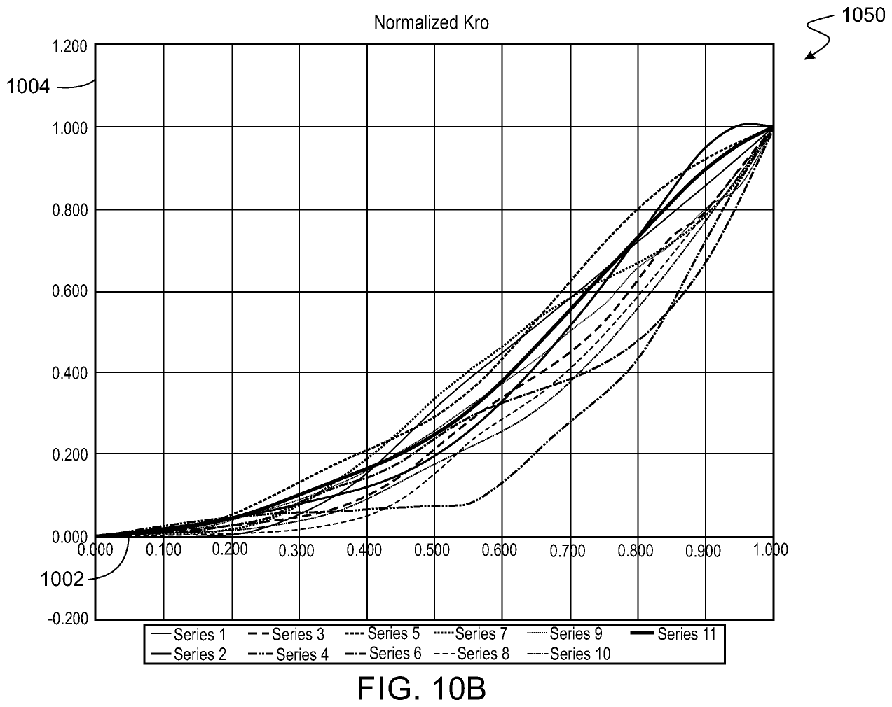

FIG. 10A is a graph showing how an average oil relative permeability (Kro) curve 1002 fits within the range of the Kro data, according to some implementations of the present disclosure. FIG. 10B is a graph showing how an average water relative permeability (Krw) curve 152 fits within the range of the Krw data, according to some implementations of the present disclosure. The curves are plotted relative to a water saturation axis 1002 (e.g., a percentage) and a relative permeability axis 1004 (e.g., a percentage).

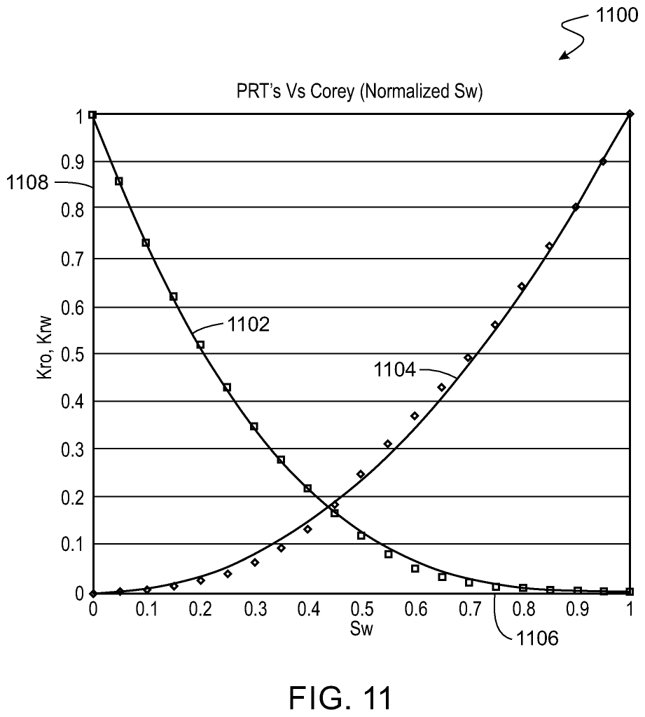

FIG. 11 is a plot 1100 showing an example of curve matching, according to some implementations of the present disclosure. In this example, a No curve 1102 and a Nw curve 1104 are plotted relative to a Sw axis 1106 and a Kro, Krw axis 1108. Curve matching can be done using either a Corey match (matching average results) or using by using a Corey equation, though visual matching can also be used.

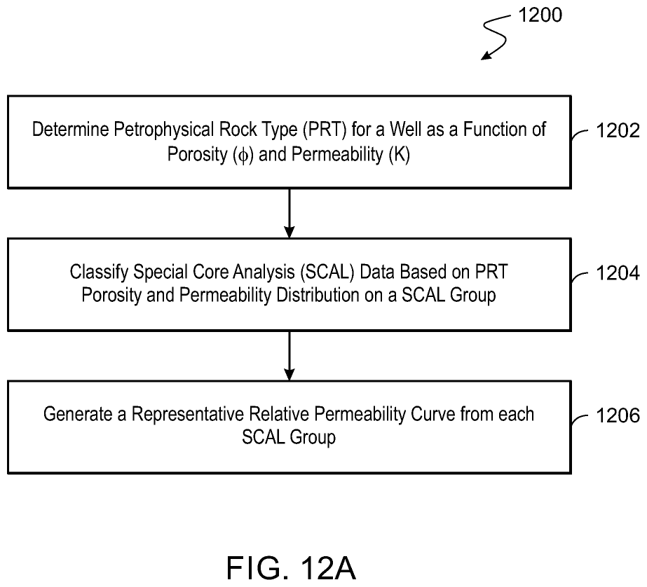

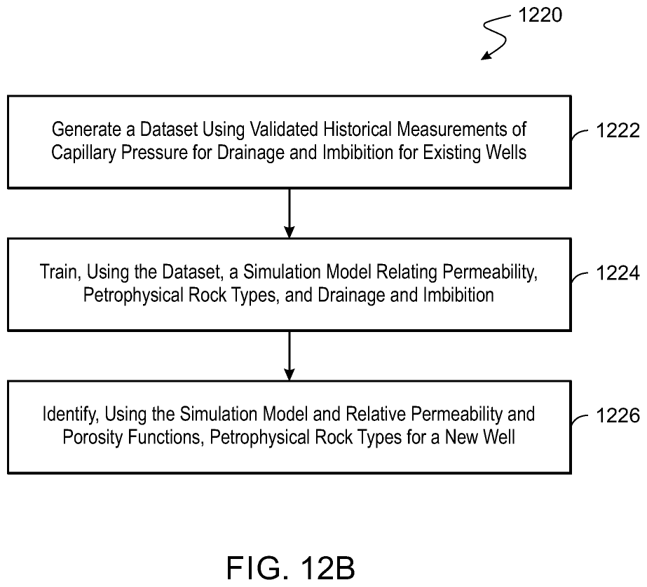

FIG. 12A is a flow chart of an example of a method 1200 for generating representative relative permeability curves, according to some implementations of the present disclosure. For clarity of presentation, the description that follows generally describes method 1200 in the context of the other figures in this description. However, it will be understood that method 1200 can be performed, for example, by any suitable system, environment, software, and hardware, or a combination of systems, environments, software, and hardware, as appropriate. In some implementations, various steps of method 1200 can be run in parallel, in combination, in loops, or in any order.

At 1202, PRT is determined for a well as function of porosity (Φ) and permeability (K). For example, FIGS. 1 and 2 defined processes for determining PRT. From 1202, method 1200 proceeds to 1204.

At 1204, SCAL data is classified based on PRT porosity and permeability distribution on a SCAL group. From 1204, method 1200 proceeds to 1206.

At 1206, a representative relative permeability curve is generated from each SCAL group. For example, relative permeability curves 506 as described with respect to FIG. 5 can be produced. After 1226, method 1220 can stop.

In some implementations, after the generating the Kr curve for each PRT, the PRT can serve as a function of porosity and permeability, which means that the PRT is located on a porosity/permeability chart, making regions on that charts. As a result, for a carbonate reservoir at any layer, the porosity and permeability can be used to determine the Kr curve. In another example, initial water saturation or residual oil saturation or maximum value of Krw can be modified. This can give the engineer more space to use their data, based on reservoir behavior, using start and end points that are usually different for each reservoir and are changeable.

In some implementations, e.g., on green fields, (Φ, K) are already known from the results of performing routine core analysis, but not enough SCAL data exists to generate a representative relative permeability curve. In this case, (Φ, K) are used for the PRT distribution that is standardized. In some cases, if a few SCAL experiments are performed on the green field, the results of the experiments can be used, which may change Sor or other parameters. If no SCAL experiments are performed on the green field, then the Kr curve can be used right away. In some cases, the results of experiments on minerals or dolomite can be used. As an example, performing these steps can occur as described with reference to FIGS. 3 and 4. After 1206, method 1200 can stop.

FIG. 12B is a flow chart of an example of a method 1220 for identifying petrophysical rock types for a new well, according to some implementations of the present disclosure. For clarity of presentation, the description that follows generally describes method 1220 in the context of the other figures in this description. However, it will be understood that method 1220 can be performed, for example, by any suitable system, environment, software, and hardware, or a combination of systems, environments, software, and hardware, as appropriate. In some implementations, various steps of method 1220 can be run in parallel, in combination, in loops, or in any order.

At 1222, a dataset is generated using validated historical measurements of capillary pressure for drainage and imbibition for existing wells. For example, the validated historical measurements can include centrifuge imbibition, maximum water relative permeability, and residual oil saturation. It is noted that porosity and permeability can be obtained without using the simulation model, as the static model can suffice. From 1222, method 1220 proceeds to 1224.

At 1224, a simulation model relating permeability, petrophysical rock types, and drainage and imbibition is trained using the dataset. For example, a relative permeability function corresponding to each rock type can be generated using the dataset. The petrophysical rock types can be identified based on Winland and Lucia techniques, for example. This step can occur even though a simulation is not needed for Kr or PRT generation. From 1224, method 1220 proceeds to 1226.

At 1226, petrophysical rock types for a new well are identified using the simulation model and relative permeability and porosity functions. For example, the simulation model can assign the PRT along the Kr curve. After 1226, method 1220 can stop.

For any new fields in which a lack of SCAL data exists, techniques of the present disclosure can be used to more accurately and efficiently use the Kr curve to run simulations. For example, SCAL data used to develop relative permeability curves can be used as input to simulations in order to generate predictions for the reservoir. Samples or geological models may exist along with porosity and permeability cells for redeveloping existing operation reservoir simulation models. When not enough SCAL data exists, a Kr curve can be developed for each PRT. This can be useful because the start point (Swi) and end points (Sor and Krw_max) are already known on which to base reservoir behavior, e.g., No (oil behavior) and (Nw water behavior) using start and end points. The techniques provide more accurate and faster ways to develop relative permeability curves for simulation models on a new field or an existing redeveloped field.

In some implementations, in addition to (or in combination with) any previously-described features, techniques of the present disclosure can include the following. Outputs of the techniques of the present disclosure can be performed before, during, or in combination with wellbore operations, such as to provide inputs to change the settings or parameters of equipment used for drilling. Examples of wellbore operations include forming/drilling a wellbore, hydraulic fracturing, and producing through the wellbore, to name a few. The wellbore operations can be triggered or controlled, for example, by outputs of the methods of the present disclosure. In some implementations, customized user interfaces can present intermediate or final results of the above described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or “app”), or at a central processing facility. The presented information can include suggestions, such as suggested changes in parameters or processing inputs, that the user can select to implement improvements in a production environment, such as in the exploration, production, and/or testing of petrochemical processes or facilities. For example, the suggestions can include parameters that, when selected by the user, can cause a change to, or an improvement in, drilling parameters (including drill bit speed and direction) or overall production of a gas or oil well. The suggestions, when implemented by the user, can improve the speed and accuracy of calculations, streamline processes, improve models, and solve problems related to efficiency, performance, safety, reliability, costs, downtime, and the need for human interaction. In some implementations, the suggestions can be implemented in real-time, such as to provide an immediate or near-immediate change in operations or in a model. The term real-time can correspond, for example, to events that occur within a specified period of time, such as within one minute or within one second. Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to the settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart, or are located in different countries or other jurisdictions.

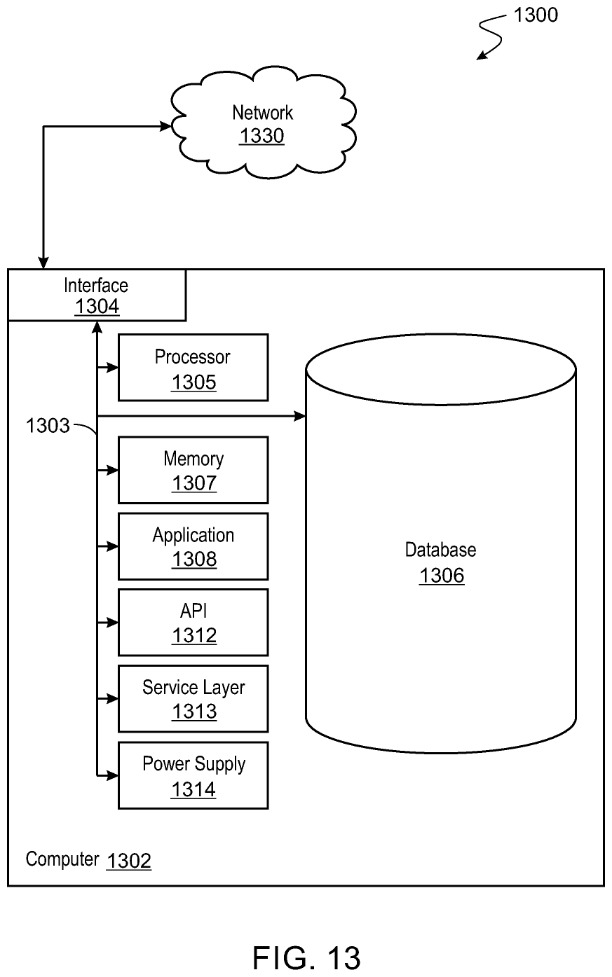

FIG. 13 is a block diagram of an example computer system 1300 used to provide computational functionalities associated with described algorithms, methods, functions, processes, flows, and procedures described in the present disclosure, according to some implementations of the present disclosure. The illustrated computer 1302 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 1302 can include input devices such as keypads, keyboards, and touch screens that can accept user information. Also, the computer 1302 can include output devices that can convey information associated with the operation of the computer 1302. The information can include digital data, visual data, audio information, or a combination of information. The information can be presented in a graphical user interface (UI) (or GUI).

The computer 1302 can serve in a role as a client, a network component, a server, a database, a persistency, or components of a computer system for performing the subject matter described in the present disclosure. The illustrated computer 1302 is communicably coupled with a network 1330. In some implementations, one or more components of the computer 1302 can be configured to operate within different environments, including cloud-computing-based environments, local environments, global environments, and combinations of environments.

At a top level, the computer 1302 is an electronic computing device operable to receive, transmit, process, store, and manage data and information associated with the described subject matter. According to some implementations, the computer 1302 can also include, or be communicably coupled with, an application server, an email server, a web server, a caching server, a streaming data server, or a combination of servers.

The computer 1302 can receive requests over network 1330 from a client application (for example, executing on another computer 1302). The computer 1302 can respond to the received requests by processing the received requests using software applications. Requests can also be sent to the computer 1302 from internal users (for example, from a command console), external (or third) parties, automated applications, entities, individuals, systems, and computers.

Each of the components of the computer 1302 can communicate using a system bus 1303. In some implementations, any or all of the components of the computer 1302, including hardware or software components, can interface with each other or the interface 1304 (or a combination of both) over the system bus 1303. Interfaces can use an application programming interface (API) 1312, a service layer 1313, or a combination of the API 1312 and service layer 1313. The API 1312 can include specifications for routines, data structures, and object classes. The API 1312 can be either computer-language independent or dependent. The API 1312 can refer to a complete interface, a single function, or a set of APIs.

The service layer 1313 can provide software services to the computer 1302 and other components (whether illustrated or not) that are communicably coupled to the computer 1302. The functionality of the computer 1302 can be accessible for all service consumers using this service layer. Software services, such as those provided by the service layer 1313, can provide reusable, defined functionalities through a defined interface. For example, the interface can be software written in JAVA, C++, or a language providing data in extensible markup language (XML) format. While illustrated as an integrated component of the computer 1302, in alternative implementations, the API 1312 or the service layer 1313 can be stand-alone components in relation to other components of the computer 1302 and other components communicably coupled to the computer 1302. Moreover, any or all parts of the API 1312 or the service layer 1313 can be implemented as child or sub-modules of another software module, enterprise application, or hardware module without departing from the scope of the present disclosure.

The computer 1302 includes an interface 1304. Although illustrated as a single interface 1304 in FIG. 13, two or more interfaces 1304 can be used according to particular needs, desires, or particular implementations of the computer 1302 and the described functionality. The interface 1304 can be used by the computer 1302 for communicating with other systems that are connected to the network 1330 (whether illustrated or not) in a distributed environment. Generally, the interface 1304 can include, or be implemented using, logic encoded in software or hardware (or a combination of software and hardware) operable to communicate with the network 1330. More specifically, the interface 1304 can include software supporting one or more communication protocols associated with communications. As such, the network 1330 or the interface's hardware can be operable to communicate physical signals within and outside of the illustrated computer 1302.

The computer 1302 includes a processor 1305. Although illustrated as a single processor 1305 in FIG. 13, two or more processors 1305 can be used according to particular needs, desires, or particular implementations of the computer 1302 and the described functionality. Generally, the processor 1305 can execute instructions and can manipulate data to perform the operations of the computer 1302, including operations using algorithms, methods, functions, processes, flows, and procedures as described in the present disclosure.

The computer 1302 also includes a database 1306 that can hold data for the computer 1302 and other components connected to the network 1330 (whether illustrated or not). For example, database 1306 can be an in-memory, conventional, or a database storing data consistent with the present disclosure. In some implementations, database 1306 can be a combination of two or more different database types (for example, hybrid in-memory and conventional databases) according to particular needs, desires, or particular implementations of the computer 1302 and the described functionality. Although illustrated as a single database 1306 in FIG. 13, two or more databases (of the same, different, or combination of types) can be used according to particular needs, desires, or particular implementations of the computer 1302 and the described functionality. While database 1306 is illustrated as an internal component of the computer 1302, in alternative implementations, database 1306 can be external to the computer 1302.

The computer 1302 also includes a memory 1307 that can hold data for the computer 1302 or a combination of components connected to the network 1330 (whether illustrated or not). Memory 1307 can store any data consistent with the present disclosure. In some implementations, memory 1307 can be a combination of two or more different types of memory (for example, a combination of semiconductor and magnetic storage) according to particular needs, desires, or particular implementations of the computer 1302 and the described functionality. Although illustrated as a single memory 1307 in FIG. 13, two or more memories 1307 (of the same, different, or combination of types) can be used according to particular needs, desires, or particular implementations of the computer 1302 and the described functionality. While memory 1307 is illustrated as an internal component of the computer 1302, in alternative implementations, memory 1307 can be external to the computer 1302.

The application 1308 can be an algorithmic software engine providing functionality according to particular needs, desires, or particular implementations of the computer 1302 and the described functionality. For example, application 1308 can serve as one or more components, modules, or applications. Further, although illustrated as a single application 1308, the application 1308 can be implemented as multiple applications 1308 on the computer 1302. In addition, although illustrated as internal to the computer 1302, in alternative implementations, the application 1308 can be external to the computer 1302.

The computer 1302 can also include a power supply 1314. The power supply 1314 can include a rechargeable or non-rechargeable battery that can be configured to be either user- or non-user-replaceable. In some implementations, the power supply 1314 can include power-conversion and management circuits, including recharging, standby, and power management functionalities. In some implementations, the power supply 1314 can include a power plug to allow the computer 1302 to be plugged into a wall socket or a power source to, for example, power the computer 1302 or recharge a rechargeable battery.

There can be any number of computers 1302 associated with, or external to, a computer system containing computer 1302, with each computer 1302 communicating over network 1330. Further, the terms “client,” “user,” and other appropriate terminology can be used interchangeably, as appropriate, without departing from the scope of the present disclosure. Moreover, the present disclosure contemplates that many users can use one computer 1302 and one user can use multiple computers 1302.

Described implementations of the subject matter can include one or more features, alone or in combination.

For example, in a first implementation, a computer-implemented method includes the following. Petrophysical rock type (PRT) is determined for a well as a function of porosity (Φ) and permeability (K). Special core analysis (SCAL) data is classified based on PRT porosity and permeability distribution on a SCAL group. A representative relative permeability curve is generated from each SCAL group.

The foregoing and other described implementations can each, optionally, include one or more of the following features:

A first feature, combinable with any of the following features, where petrophysical rock types are identified based on Winland and Lucia techniques.

A second feature, combinable with any of the previous or following features, the method further including determining a standardized PRT distribution from (Φ, K) of a green field.

A third feature, combinable with any of the previous or following features, where determining the PRT for a well the is further based on validated historical measurements.

A fourth feature, combinable with any of the previous or following features, where the validated historical measurements include centrifuge imbibition, maximum water relative permeability, and residual oil saturation.

A fifth feature, combinable with any of the previous or following features, the method further including determining, using porosity and permeability values from a porosity/permeability chart for a PRT porosity and permeability distribution, a Kr curve for a carbonate reservoir at a given layer.

A sixth feature, combinable with any of the previous or following features, the method further including modifying, using the porosity/permeability chart, initial water saturation or residual oil saturation or maximum value of Krw.

In a second implementation, a non-transitory, computer-readable medium stores one or more instructions executable by a computer system to perform operations including the following. Petrophysical rock type (PRT) is determined for a well as a function of porosity (Φ) and permeability (K). Special core analysis (SCAL) data is classified based on PRT porosity and permeability distribution on a SCAL group. A representative relative permeability curve is generated from each SCAL group.

The foregoing and other described implementations can each, optionally, include one or more of the following features:

A first feature, combinable with any of the following features, where petrophysical rock types are identified based on Winland and Lucia techniques.

A second feature, combinable with any of the previous or following features, the method further including determining a standardized PRT distribution from (Φ, K) of a green field.

A third feature, combinable with any of the previous or following features, where determining the PRT for a well the is further based on validated historical measurements.

A fourth feature, combinable with any of the previous or following features, where the validated historical measurements include centrifuge imbibition, maximum water relative permeability, and residual oil saturation.

A fifth feature, combinable with any of the previous or following features, the method further including determining, using porosity and permeability values from a porosity/permeability chart for a PRT porosity and permeability distribution, a Kr curve for a carbonate reservoir at a given layer.

A sixth feature, combinable with any of the previous or following features, the method further including modifying, using the porosity/permeability chart, initial water saturation or residual oil saturation or maximum value of Krw.

In a third implementation, a computer-implemented system includes one or more processors and a non-transitory computer-readable storage medium coupled to the one or more processors and storing programming instructions for execution by the one or more processors. The programming instructions instruct the one or more processors to perform operations including the following. Petrophysical rock type (PRT) is determined for a well as a function of porosity (Φ) and permeability (K). Special core analysis (SCAL) data is classified based on PRT porosity and permeability distribution on a SCAL group. A representative relative permeability curve is generated from each SCAL group.

The foregoing and other described implementations can each, optionally, include one or more of the following features:

A first feature, combinable with any of the following features, where petrophysical rock types are identified based on Winland and Lucia techniques.

A second feature, combinable with any of the previous or following features, the method further including determining a standardized PRT distribution from (Ø, K) of a green field.

A third feature, combinable with any of the previous or following features, where determining the PRT for a well the is further based on validated historical measurements.

A fourth feature, combinable with any of the previous or following features, where the validated historical measurements include centrifuge imbibition, maximum water relative permeability, and residual oil saturation.

A fifth feature, combinable with any of the previous or following features, the method further including determining, using porosity and permeability values from a porosity/permeability chart for a PRT porosity and permeability distribution, a Kr curve for a carbonate reservoir at a given layer.

A sixth feature, combinable with any of the previous or following features, the method further including modifying, using the porosity/permeability chart, initial water saturation or residual oil saturation or maximum value of Krw.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. For example, the signal can be a machine-generated electrical, optical, or electromagnetic signal that is generated to encode information for transmission to a suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatuses, devices, and machines for processing data, including by way of example, a programmable processor, a computer, or multiple processors or computers. The apparatus can also include special purpose logic circuitry including, for example, a central processing unit (CPU), a field-programmable gate array (FPGA), or an application-specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, such as LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub-programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory.

Graphics processing units (GPUs) can also be used in combination with CPUs. The GPUs can provide specialized processing that occurs in parallel to processing performed by CPUs. The specialized processing can include artificial intelligence (AI) applications and processing, for example. GPUs can be used in GPU clusters or in multi-GPU computing.

A computer can include, or be operatively coupled to, one or more mass storage devices for storing data. In some implementations, a computer can receive data from, and transfer data to, the mass storage devices including, for example, magnetic, magneto-optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer-readable media (transitory or non-transitory, as appropriate) suitable for storing computer program instructions and data can include all forms of permanent/non-permanent and volatile/non-volatile memory, media, and memory devices. Computer-readable media can include, for example, semiconductor memory devices such as random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer-readable media can also include, for example, magnetic devices such as tape, cartridges, cassettes, and internal/removable disks. Computer-readable media can also include magneto-optical disks and optical memory devices and technologies including, for example, digital video disc (DVD), CD-ROM, DVD+/−R, DVD-RAM, DVD-ROM, HD-DVD, and BLU-RAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated into, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that the user uses. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch-screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship.

Cluster file systems can be any file system type accessible from multiple servers for read and update. Locking or consistency tracking may not be necessary since the locking of exchange file system can be done at the application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations. It should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system including a computer memory interoperably coupled with a hardware processor configured to perform the computer-implemented method or the instructions stored on the non-transitory, computer-readable medium.

What is claimed is:

1. A computer-implemented method, comprising:
determining petrophysical rock type (PRT) for a well as a function of porosity (Φ) and permeability (K);
classifying special core analysis (SCAL) data based on PRT porosity and permeability distribution on a SCAL group, and
generating a representative relative permeability curve from each SCAL group.

2. The computer-implemented method of claim 1, wherein petrophysical rock types are identified based on Winland and Lucia techniques.

3. The computer-implemented method of claim 1, further comprising:
determining a standardized PRT distribution from (Φ, K) of a green field.

4. The computer-implemented method of claim 1, wherein determining the PRT for a well the is further based on validated historical measurements.

5. The computer-implemented method of claim 4, wherein the validated historical measurements include centrifuge imbibition, maximum water relative permeability, and residual oil saturation.

6. The computer-implemented method of claim 1, further comprising:
determining, using porosity and permeability values from a porosity/permeability chart for a PRT porosity and permeability distribution, a Kr curve for a carbonate reservoir at a given layer.

7. The computer-implemented method of claim 1, further comprising:
modifying, using the porosity/permeability chart, initial water saturation or residual oil saturation or maximum value of Krw.

8. A non-transitory, computer-readable medium storing one or more instructions executable by a computer system to perform operations comprising:
determining petrophysical rock type (PRT) for a well as a function of porosity (Φ) and permeability (K);
classifying special core analysis (SCAL) data based on PRT porosity and permeability distribution on a SCAL group, and
generating a representative relative permeability curve from each SCAL group.

9. The non-transitory, computer-readable medium of claim 8, wherein petrophysical rock types are identified based on Winland and Lucia techniques.

10. The non-transitory, computer-readable medium of claim 8, the operations further comprising:
determining a standardized PRT distribution from (Φ, K) of a green field.

11. The non-transitory, computer-readable medium of claim 8, wherein determining the PRT for a well the is further based on validated historical measurements.

12. The non-transitory, computer-readable medium of claim 11, wherein the validated historical measurements include centrifuge imbibition, maximum water relative permeability, and residual oil saturation.

13. The non-transitory, computer-readable medium of claim 8, the operations further comprising:
determining, using porosity and permeability values from a porosity/permeability chart for a PRT porosity and permeability distribution, a Kr curve for a carbonate reservoir at a given layer.

14. The non-transitory, computer-readable medium of claim 8, the operations further comprising:
modifying, using the porosity/permeability chart, initial water saturation or residual oil saturation or maximum value of Krw.

15. A computer-implemented system, comprising:
one or more processors; and
a non-transitory computer-readable storage medium coupled to the one or more processors and storing programming instructions for execution by the one or more processors, the programming instructions instructing the one or more processors to perform operations comprising:
determining petrophysical rock type (PRT) for a well as a function of porosity (Φ) and permeability (K);
classifying special core analysis (SCAL) data based on PRT porosity and permeability distribution on a SCAL group, and
generating a representative relative permeability curve from each SCAL group.

16. The computer-implemented system of claim 15, wherein petrophysical rock types are identified based on Winland and Lucia techniques.

17. The computer-implemented system of claim 15, the operations further comprising:
determining a standardized PRT distribution from (Φ, K) of a green field.

18. The computer-implemented system of claim 15, wherein determining the PRT for a well the is further based on validated historical measurements.

19. The computer-implemented system of claim 18, wherein the validated historical measurements include centrifuge imbibition, maximum water relative permeability, and residual oil saturation.

20. The computer-implemented system of claim 15, the operations further comprising:
determining, using porosity and permeability values from a porosity/permeability chart for a PRT porosity and permeability distribution, a Kr curve for a carbonate reservoir at a given layer.
